(19) United States
(12) Patent Application Publication
(10) Pub. No.: US 2006/0103422 A1
(43) Pub. Date: May 18, 2006

(54) Low leakage, source modulated, differential output level shifter

(76) Inventor: Kenneth G. Richardson, Erie, CO (US)

Correspondence Address: LSI LOGIC CORPORATION, 1621 BARBER LANE, MS: D-106, MILPITAS, CA, 95035, US

(21) Appl. No.: 10/988,369

(22) Filed: Nov. 12, 2004

(51) Int. Cl. H03K 19/0175

(52) U.S. Cl. 326/80

(57) ABSTRACT

Disclosed is a low leakage, source modulated, differential output level shifter that has reduced duty-cycle distortion and better crossover symmetry. The system utilizes P-type assisting transistors that drive the sources of the P-type cross-connected transistors in the level shifter. In this fashion, the width to length ratio of the N-type transistors to the P-type transistors can be reduced causing lower leakage in the N-type transistors, quicker switching in the P-type, cross-connected transistors which results in better crossover symmetry.

### BACKGROUND OF THE INVENTION

a. Field of the Invention

The present invention generally pertains to level shifters and more specifically to differential output level shifters.

b. Description of the Background

Level shifters are used to convert core level signals from, for example, core logic to input/output (I/O) or mixed signal levels, and vice versa. Of the two conversion problems, level shifting up is generally more difficult than level shifting down. As a result, a variety of approaches are used for level shifting up. When the ratio of a core voltage to an I/O voltage or mixed signal voltage level exceeds the ratio 1:2, the problem becomes more difficult.

With core voltages of 1.2 volts and I/O voltages of 3.3 volts, the ratio approach is 1:3. Leakage becomes a problem as well as duty-cycle distortion and crossover symmetry.

### SUMMARY OF THE INVENTION

The present invention overcomes the disadvantages and limitations of the prior art by adding assisting transistors that provide source modulation to the cross-connected P-type transistors of the level shifter.

The present invention may therefore comprise a low leakage, source modulated differential output level shifter that shifts an input signal at a first voltage to a pair of level shifted differential output signals at a second higher voltage comprising: a control circuit having two series connected inverters that generate a control signal that switches between a ground potential and the first voltage nearly simultaneously with the input signal, and a single inverter that generates a control bar signal that switches from the ground potential to the first voltage as a complementary signal; a cross-coupled level shifter having two cross-coupled P-type transistors that have gates that are connected to the level shifted differential output signal, and two N-type transistors that are connected to the drains of the cross-coupled P-type transistors, the two N-type transistors alternately coupling the cross-coupled P-type transistors to, and isolating the cross-coupled P-type transistors from, the ground potential; and two P-type assisting transistors having drains that are connected to sources of the two cross-coupled P-type transistors, and sources that are connected to the second higher voltage, that assist the cross-coupled P-type transistors in switching states by controlling current and voltage applied to the sources of the two cross-coupled P-type transistors.

The present invention may further comprise a method of level shifting an input signal that alternates between a ground potential and a first voltage to generate a pair of level shifted differential output signals that alternate between ground potential and a second higher voltage comprising: generating a control signal from the input signal using a pair of inverters that switch between the ground potential and the first voltage; generating a control bar signal from the input signal using a single inverter that switches between the first voltage and the ground potential nearly simultaneously with the control signal; switching a level shifter between the ground potential and the second higher voltage to generate a pair of level shifted differential output signals using two cross-coupled P-type transistors having gates that are connected to the pair of level shifted differential output signals, and two N-type transistors that are connected to the drains of the cross-coupled P-type transistors, the two N-type transistors alternately coupling the cross-coupled P-type transistors to, and isolating the cross-coupled P-type transistors from, the ground potential; assisting the cross-coupled P-type transistors and the N-type transistors in switching states by controlling the current and voltage applied to the cross-coupled P-type transistors using two P-type assisting transistors that have sources connected to the supply of the second higher voltage, drains that are connected to the sources of the cross-coupled P-type transistors and gates that are connected to the control signal and the control bar signal.

Advantages of the present invention include, but not by way of limitation or necessity, a reduction in leakage current in the voltage shifter, reduction in duty-cycle distortion and better crossover symmetry.

### BRIEF DESCRIPTION OF THE DRAWINGS

FIG. 1 is a block diagram of one embodiment of the low leakage, source modulated, differential output level shifter 100.

FIG. 2 is a more detailed block diagram of the embodiment of FIG. 1 of the low leakage, source modulated, differential output level shifter 100.

### DETAILED DESCRIPTION OF THE PREFERRED EMBODIMENT OF THE INVENTION

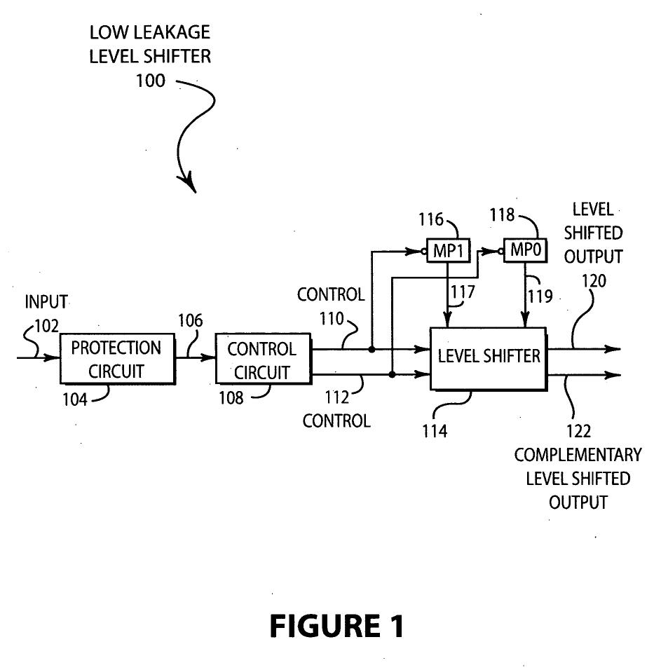

FIG. 1 is a schematic block diagram of one embodiment of a low leakage, source modulated, differential output level shifter 100. The purpose of the level shifter 100, illustrated in FIG. 1, is to shift a low level input 102, that may be at a low voltage, such as 1.2 volts or other low voltage, that may emanate from the logic core of a chip or other source to a differential output at a higher voltage, such as 3.3 volts. The differential output is the level shifted output 120 and the complementary level shifted output 122. For example, when the input 102 shifts from 0 to 1.2 volts, the level shifted output 120 switches from 0 to 3.3 volts. At the same time, the complementary (differential) level shifted output 122 shifts from 3.3 volts to zero volts. The voltage level at which the output 120 and complementary output 122 cross is called the crossover point. The source modulation provided by assisting transistor 116 (MP1) and assisting transistor 118 (MP0) create better symmetry and higher crossover voltages. In this fashion, duty-cycle distortion is improved.

As also shown in FIG. 1, input 102 is applied to a protection circuit 104 that protects the level shifter 100 from circuitry that produces the input 102. The output signal 106 from the protection circuitry is applied to a control circuit 108. The control circuit 108 generates a control output signal 110 and a control bar output signal 112. Control signal 110, in the case of a 1.2 voltage circuit, is a signal that switches from 0 to 1.2 volts simultaneously when input 102 switches from 0 to 1.2 volts, minus delays created by protection circuit 104 and control circuit 108. The control bar output 112 is a complementary output that switches from 1.2 volts to zero volts. Control signal 110 is applied to level shifter 114 and to assisting transistor 116 (MP1) which is a P-type transistor. Control bar output 112 is applied to level shifter 114 and to assisting transistor 118 (MP0) which is a P-type transistor. Since assisting transistors 116, 118 are both P-type transistors, when the signal level applied to the gates of assisting transistors 116, 118 goes high, these transistors are turned off. Conversely, when the signals applied to the gates of these transistors goes low, these transistors turn on. The drain 117 of assisting transistor 116 and the drain 119 of assisting transistor 118 provide current to the sources of transistors located in the level shifter 114, as described below, that assist in the switching of those transistors and lower the width to length ratio of the transistors in the level shifter 114, creating quicker switchovers, higher crossover voltages, lower duty-cycle distortion and reduced leakage in the level shifter 114, as described below.

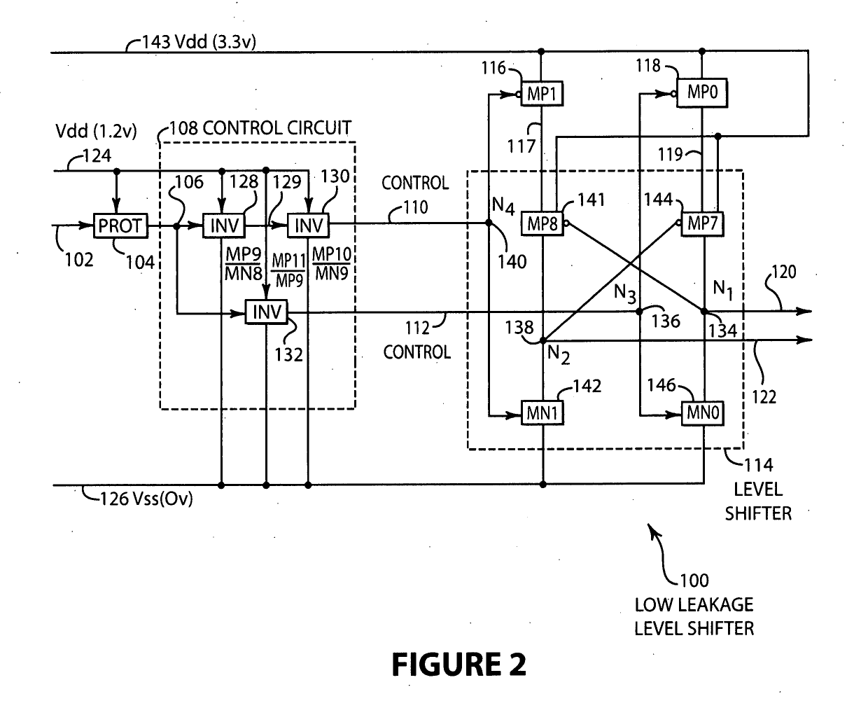

FIG. 2 is a more detailed block diagram of the low leakage, source modulated, differential output level shifter 100 illustrated in FIG. 1. As shown in FIG. 2, the input 102 is applied to the protection circuit 104. The output of the protection circuit 106 is applied to inverter 128 and inverter 132. Inverter 128 and inverter 132 invert the 1.2 volt input signal. In other words, when the input signal 102 goes from zero to 1.2 volts, the output inverters 128 and 132 go from 1.2 volts to zero volts. The output 129 of inverter 128 is applied to inverter 130. Inverter 130 again inverts the signal 129 to produce the output control signal 110. Hence, control signal 110 switches in the same direction as the input signal 102 since the input signal 102 has been inverted twice by inverters 128, 130. On the other hand, inverter 132 inverts the input signal 102 once to produce the control bar signal 112 that switches oppositely from the input signal 102. Inverters 128, 130 and 132 produce delays. However, it has been found that better symmetry can be achieved with two inverters 128, 130, that produce the control signal 110, and one inverter 132, that produces the control bar signal 112, rather than using a single inverter to produce a control signal 110 and control bar signal 112. Vdd 124 which constitutes 1.2 volts is connected to the protection circuit 104 and inverters 128, 130, 132.

As also shown in FIG. 2, the control signal 110 is applied to node 140. Node 140 is connected to the gate of assisting transistor 116 (MP1) and to the gate of transistor 142 (MN1). The control bar signal 112 is connected to node 136. Node 136 is connected to the gate of transistor 118 (MP0) and to the gate of transistor 146 (MN0). The gate of transistor 141 (MP8) is cross-couple connected to node 134. Node 134 constitutes the node shifted output 120. Similarly, the gate of transistor 144 is cross-couple connected to node 138. Node 138 is connected to the complementary level shifted output 122.

As shown in FIG. 2, the control circuit 108 includes the inverters 128, 130, 132. The level shifter 114 includes transistors 141, 142, 144, 146. The source voltage Vdd 148, which is 3.3. volts, is applied to transistors 116, 118, 141, 144. Voltage Vss 126, which is at ground potential, is connected to inverters 128, 130, 132 and transistors 142, 146.

In operation, it will be assumed that the input signal 102 is 1.2 volts (high). In that case, control signal 110 is at 1.2 volts (high) and control bar signal 112 is at zero volts (low). Assisting transistor 116 will be partially turned off because it is a P-type transistor, and transistor 142 will be partially turned on because it is an N-type transistor. Control bar signal 112 is at zero volts, which means that node 136 is at zero volts. Assisting transistor 118 is fully turned on, and transistor 146 is fully turned off. Since transistor 146 is turned off, node 134 is isolated from ground potential. Transistor 142 is partially turned on, which lowers the voltage at node 138. As the voltage is lowered at node 138, transistor 144 turns on. As transistor 144 turns on, the voltage rises at node 134. As the voltage rises at node 134, transistor 141 begins to turn off. The more that transistor 141 turns off, the lower the voltage at node 138 and the more transistor 144 turns on. When the voltage at node 138 reaches zero, transistor 144 is fully turned on, which increases the voltage at node 134 causing transistor 141 to completely turn off. When the voltage at node 134 reaches 3.3 volts, transistor 141 is completely turned off causing the voltage at node 138 to reach zero volts. Hence, output 120, which is connected to node 134, is at 3.3 volts, while complementary output 122, which is connected to node 138, is at zero volts. Since assisting transistor 116 is partially turned on, the voltage on source 117 of transistor 141 is reduced. The difference in voltage between the source and gate of transistor 141 is therefore reduced which assists transistor 141 in turning off. Assisting transistor 118, on the other hand, is fully turned on, which increases the supply current to the source 119 of transistor 144. This assists transistor 144 in turning on.

When the input 102 switches from 1.2 volts to zero volts, control 110 switches from 1.2 volts to zero volts, and control bar signal 112 switches from zero volts to 1.2 volts. This causes assisting transistor 116 to fully turn on and transistor 142 to fully turn off. Assisting transistor 118 partially turns off while transistor 146 partially turns on. Since transistor 142 is fully turned off, the voltage level at node 138 rises, which causes transistor 144 to begin to turn off. When transistor 146 is partially turned on, this causes the voltage at node 134 to go down, which causes transistor 141 to turn on. As transistor 141 turns on, the voltage at node 138 increases. When the voltage at 138 increases, transistor 144 turns off, which causes the voltage at 134 to go down. Since assisting transistor 116 is fully turned on, current from the drain of assisting transistor 116 is applied to the source of transistor 141, which assists transistor 141 in turning on. Since assisting transistor 118 is partially turned off, the difference in voltage between the gate (134) and source (117) of transistor 141 is reduced, which assists transistor 144 in turning off. In this fashion, assisting transistor 116 assists transistor 141 in switching on, while assisting transistor 118 assists transistor 144 in switching off by controlling the sources 117, 119, respectively.

The assistance provided by assisting transistors 116, 118 in switching transistors 141, 144, respectively, allows the size of transistors 142, 146 to be reduced in size. Normally, the width to length ratio of the N-type transistors 142, 146 to the P-type transistors 141, 144, without the assistance of transistors 116, 118 would be 50:1. The assistance provided by assisting transistors 116, 118 lowers this ratio to approximately 12:1. The lower ratio of the length to width of the MN transistors to the MP transistors reduces the leakage current in transistors 142, 146. In addition, the assistance provided by assisting transistors 116, 118 causes the system to switch more quickly, which results in a crossover voltage that is much higher and provides better symmetry between the differential (complementary) signals 120, 122.

The present invention therefore provides a differential output level shifter that has low leakage, higher crossover voltages and better symmetry. This is achieved by using assisting transistors that control the current and voltages to the sources of the cross-connected P-type transistors in the level shifter which is assists both the cross-connected P-type transistors and the N-type transistors in switching states. The assisting transistors are controlled by the control and control bar signals to vary the current and voltage applied to the sources of the cross-connected P-type transistors. A reduction in the width to length ratio of the N-type transistors to the cross-connected P-type transistors reduces leakage current in the level shifter, allowing the level shifter to switch more quickly, which results in better crossover symmetry of the differential output signal.

The foregoing description of the invention has been presented for purposes of illustration and description. It is not intended to be exhaustive or to limit the invention to the precise form disclosed, and other modifications and variations may be possible in light of the above teachings. The embodiment was chosen and described in order to best explain the principles of the invention and its practical application to thereby enable others skilled in the art to best utilize the invention in various embodiments and various modifications as are suited to the particular use contemplated. It is intended that the appended claims be construed to include other alternative embodiments of the invention except insofar as limited by the prior art.

What is claimed is:

1. A low leakage, source modulated differential output level shifter that shifts an input signal at a first voltage to a pair of level shifted differential output signals at a second higher voltage comprising:
a control circuit having two series connected inverters that generate a control signal that switches between a ground potential and said first voltage nearly simultaneously with said input signal, and a single inverter that generates a control bar signal that switches from said ground potential to said first voltage as a complementary signal;
a cross-coupled level shifter having two cross-coupled P-type transistors that have gates that are connected to said level shifted differential output signal, and two N-type transistors that are connected to the drains of said cross-coupled P-type transistors, said two N-type transistors alternately coupling said cross-coupled P-type transistors to, and isolating said cross-coupled P-type transistors from, said ground potential; and
two P-type assisting transistors having drains that are connected to sources of said two cross-coupled P-type transistors, and sources that are connected to said second higher voltage, that assist the cross-coupled P-type transistors in switching states by controlling current and voltage applied to said sources of said two cross-coupled P-type transistors.

2. The level shifter of claim 1 wherein said assisting transistors comprise:
a first assisting transistor having a gate that is connected to said control signal; and
a second assisting transistor having a gate that is connected to said control bar signal.

3. The level shifter of claim 2 wherein said two cross-coupled P-type transistors comprise:
a first cross-coupled P-type transistor having a source that is connected to said drain of said first assisting transistor; and
a second cross-coupled P-type transistor having a source that is connected to said drain of said second assisting transistor.

4. The level shifter of claim 3 wherein said two N-type transistors comprise:
a first N-type transistor having a source that is connected to said drain of said first cross-coupled P-type transistor, and a drain that is connected to said ground potential; and
a second N-type transistor having a source that is connected to said drain of said second cross-coupled P-type transistor, and a drain that is connected to said ground potential.

5. A method of level shifting an input signal that alternates between a ground potential and a first voltage to generate a pair of level shifted differential output signals that alternate between ground potential and a second higher voltage comprising:
generating a control signal from said input signal using a pair of inverters that switch between said ground potential and said first voltage;
generating a control bar signal from said input signal using a single inverter that switches between said first voltage and said ground potential nearly simultaneously with said control signal;
switching a level shifter between said ground potential and said second higher voltage to generate a pair of level shifted differential output signals using two cross-coupled P-type transistors having gates that are connected to said pair of level shifted differential output signals, and two N-type transistors that are connected to the drains of said cross-coupled P-type transistors, said two N-type transistors alternately coupling said cross-coupled P-type transistors to, and isolating said cross-coupled P-type transistors from, said ground potential;
assisting said cross-coupled P-type transistors and said N-type transistors in switching states by controlling the current and voltage applied to said cross-coupled P-type transistors using two P-type assisting transistors that have sources connected to said supply of said second higher voltage, drains that are connected to said sources of said cross-coupled P-type transistors and gates that are connected to said control signal and said control bar signal.
